(19) United States
(12) Patent Application Publication
(10) Pub. No.: US 2025/0364175 A1
(43) Pub. Date: Nov. 27, 2025

(54) ISOLATION TRANSFORMER INCLUDING A GROUND RING

(71) Applicant: Texas Instruments Incorporated, Dallas, TX (US)

(72) Inventors: Jeffrey Alan West, Dallas, TX (US); Byron Williams, Plano, TX (US); Chinna Veerappan Venkatachalam, Bangalore (IN)

(21) Appl. No.: 19/095,422

(22) Filed: Mar. 31, 2025

Related U.S. Application Data
(60) Provisional application No. 63/651,383, filed on May 23, 2024.

(51) Int. Cl. H01F 27/36; H01F 27/29; H01F 41/06

(52) U.S. Cl. CPC H01F 27/36; H01F 27/29; H01F 41/06

(57) ABSTRACT

An isolation transformer including a ground ring with one or more gaps. The isolation transformer comprises a first coil, a second coil, a dielectric layer between the first coil and the second coil, and a ground ring around the first coil. In examples, the ground ring includes at least one gap in a region between a first winding portion of the first coil and a second winding portion of the first coil.

### CROSS-REFERENCE TO RELATED APPLICATIONS

This application claims the benefit of and priority to U.S. Provisional Application No. 63/651,383, filed on May 23, 2024, which is hereby fully incorporated herein by reference.

### FIELD OF THE DISCLOSURE

Disclosed implementations relate generally to the field of semiconductor devices and fabrication. More particularly, but not exclusively, the disclosed implementations relate to isolation transformers.

### BACKGROUND

Galvanic isolation is a principle of isolating functional sections of electrical systems or integrated circuits (ICs) to prevent current flow while energy or information can still be exchanged between the sections by other means, such as induction or electromagnetic waves, capacitance, or by optical, acoustic or mechanical means. Galvanic isolation is typically used where two or more electric circuits communicate but their grounds or reference nodes may be at different potentials. It is an effective method of breaking ground loops by preventing unwanted current from flowing between two units sharing a reference conductor. Galvanic isolation is also used for safety, preventing accidental current flows from reaching ground though a person's body.

Isolators are devices designed to minimize direct current (DC) and unwanted alternating current (AC) transient currents between two systems or circuits, while allowing data and power transmission between the two. In some applications, isolators also act as a barrier against high voltage in addition to allowing the system to function properly.

As advances in the design of integrated circuits and semiconductor fabrication continue to take place, improvements in microelectronic devices, including isolators, are also being concomitantly pursued.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, an isolation transformer including a ground ring with one or more gaps is disclosed. The isolation transformer may comprise a first coil, a second coil, a dielectric layer between the first coil and the second coil, and a ground ring around the first coil. In one arrangement, the ground ring includes at least one gap in a region between a first winding portion of the first coil and a second winding portion of the first coil.

In one example, a semiconductor device is disclosed, which may comprise a first circuit, a second circuit, and an isolation transformer between the first and second circuits. The isolation transformer may include a first conductive element over a substrate, the first conductive element including a first winding portion, a second winding portion and a crossover section extended between the first and second winding portions. The isolation transformer may include a ground ring around the first conductive element, where the ground ring includes a discontinuity positioned in an area between the first winding portion of the first conductive element and a centerline bisecting the crossover section. The isolation transformer may include a dielectric layer over the first conductive element and the ground ring, and a second conductive element over the dielectric layer. The second conductive element may include a first winding portion, a second winding portion and a crossover section extended between the first and second winding portions. In an example arrangement, the first and second winding portions and the crossover section of the second conductive element may respectively overlap the first and second winding portions and the crossover section of the first conductive element.

In one example, a method of fabricating a semiconductor device is disclosed. The method comprises forming a first coil over a substrate, the first coil including a crossover section extended between two adjacent winding portions of the first coil; forming a ground ring around the first coil, the ground ring including a gap in a region between the two adjacent winding portions; forming a dielectric layer over the first coil; and forming a second coil over the dielectric layer, the second coil overlapping the first coil and including a crossover section extended between two adjacent winding portions of the second coil.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIGS. 1A-1C illustrate microelectronic devices including an isolation transformer according to some examples of the present disclosure;

FIG. 1D is a side elevation view of an isolation transformer or a winding portion thereof;

FIGS. 2A and 2B illustrate isolation transformers including a ground ring having discontinuities according to some examples;

FIG. 3 illustrates a cross-sectional view of an isolation transformer including a ground ring according to some examples;

FIGS. 4A-4C illustrate two views of an isolation transformer including a ground ring according to some examples;

FIG. 5 illustrates a center tap isolation transformer including a ground ring according to an example; and

FIG. 6 is a flowchart of a method according to an example of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples will be set forth below in the context of isolation barrier implementations including transformers.

Circuit isolation, also known as galvanic isolation, prevents direct current (DC) and unwanted alternating current (AC) signals from passing from one functional block of a system or a circuit to another functional block or circuit that needs to be protected, as previously noted. Among its uses, isolation maintains signal integrity of the system or circuit by preventing high-frequency noise from propagating, protects sensitive circuitry from high-voltage spikes (e.g., during electrostatic discharge (ESD) or surge events), and provides safety for human operators.

High voltages present in certain application environments such as factory automation, motor drives, grid infrastructure and electric vehicles (EVs), etc., can be several hundred or even thousands of volts. Galvanic isolation helps resolve the challenge of designing a safe human interface in the presence of such high voltages.

In some example arrangements, isolation may be achieved by implementing one or more isolation transformers as part of an isolation barrier between two circuits, where the transformers may be configured to provide physical and electrical separation between the two circuits. In operation, the isolation transformer may exchange electrical energy from a primary coil to a secondary coil using magnetic, or inductive, coupling, while isolating and protecting sensitive electronic circuitry from discharge events.

Isolation transformers may be deployed in a variety of applications including, e.g., isolators used to isolate digital signals and transfer digital communication across an isolation barrier. In some arrangements, isolators comprising isolation transformers may be implemented in multi-channel communication systems configured to carry digitized data streams where isolation between different circuits having respective input/output (I/O) blocks may be desired. In some arrangements, I/O blocks may comprise multi-channel I/O circuits based on complementary metal oxide semiconductor (CMOS) technology, low voltage CMOS (LVCMOS) technology, etc.

Isolation transformers may comprise a pair of coils separated by a dielectric material having a suitable thickness depending on the intended isolation barrier implementation. To improve electrical performance, one or more ground rings surrounding the windings of a coil of a transformer may be provided for containing the electric field in a circuit, e.g., near high voltage (HV) components. In some implementations, the ground ring may be operable as a Faraday cage for reducing electromagnetic interference (EMI), which may enhance signal quality. Further, one or more gaps or discontinuities may be provided in a ground ring to prevent current loops from being formed in the ground ring during transformer operation in order to improve noise immunity. However, such gaps may represent structural anomalies in the ground ring, which may cause local perturbations in an electric field applied in the transformer during operation. In some examples, local electric field perturbations caused by gaps in a ground ring may render the transformer dielectric material susceptible to reduced lifetime during test and/or in the field (e.g., time-dependent dielectric breakdown or TDDB).

Examples of the present disclosure recognize the foregoing challenges and provide a transformer solution including a ground ring arrangement where one or more gaps may be placed in the ground ring surrounding a coil of the transformer at locations that reduce the risk of degrading dielectric lifetime while maintaining noise immunity. Moreover, eliminating or reducing sources of outliers during TDDB testing at increased voltages may improve the quality and/or accuracy of product specifications relating to performance parameters such as lifetime expectation at working voltage conditions. Whereas the examples of the present disclosure may provide these and other beneficial effects, no particular result is a requirement unless explicitly recited in a particular claim.

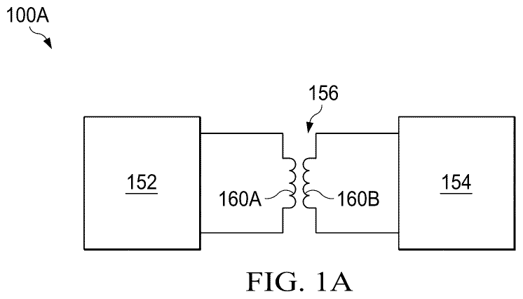

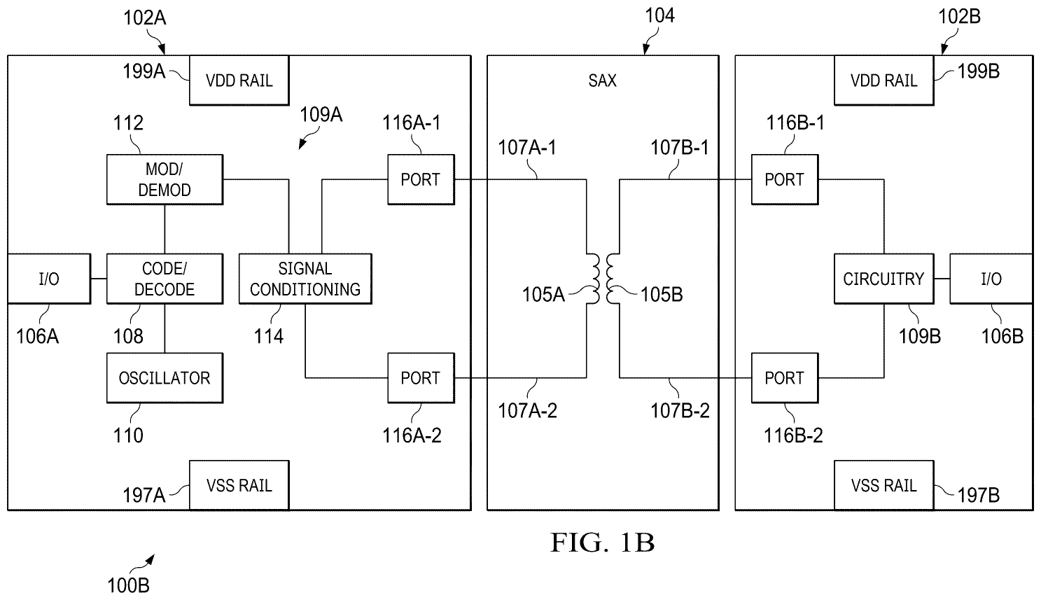

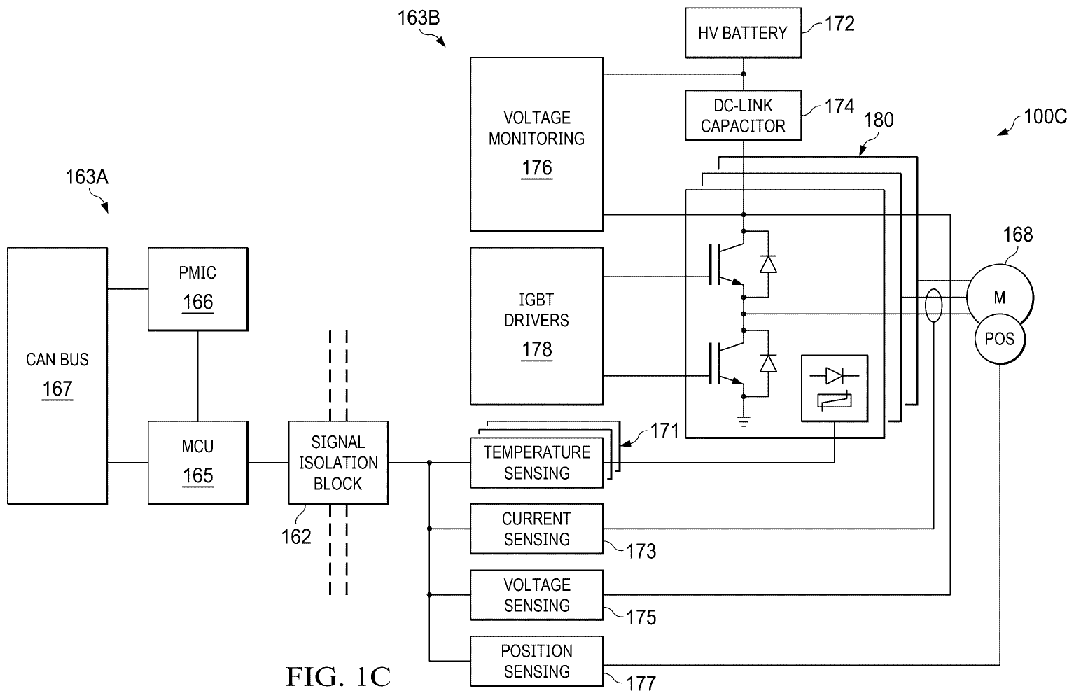

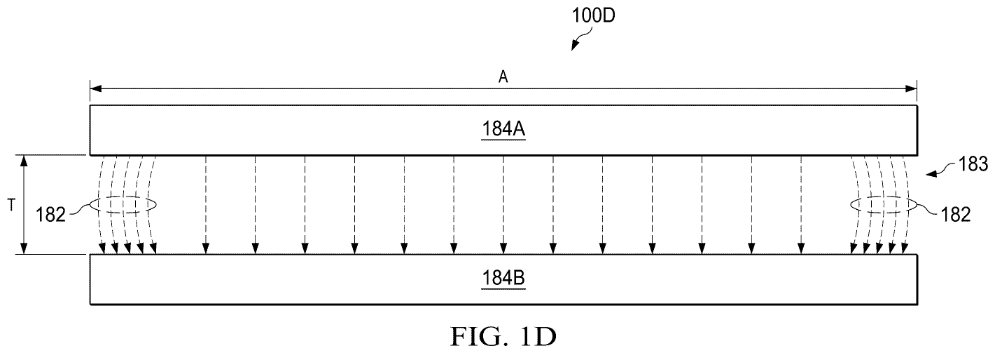

Turning to the drawings, FIG. 1A depicts a schematic diagram of a microelectronic device 100A that may include an isolation barrier between two circuits 152 and 154 according to some examples. Without limitation, the microelectronic device 100A may be configured to operate in digital, analog, and/or mixed-signal application environments where isolation between two circuits or circuit portions, e.g., circuits 152 and 154, is desired. In some arrangements, isolation may be provided by an isolation transformer 156 coupled between the circuits 152 and 154. For purposes of the present disclosure, an isolation transformer may also be referred to as a “transformer” or an “isolator” in some examples. In some arrangements, the isolation transformer 156 may be configured to operate at high voltages, e.g., 500 V, 1000 V or greater, in order to provide high voltage isolation between the circuits 152 and 154. By way of illustration, the microelectronic device 100A may be deployed in digital communication systems, servo motor control, factory automation, power supplies, solar or wind power generation, computer peripheral interfaces, data acquisition, data center infrastructure, robotic control, autonomous vehicular control including unmanned aerial and/or automotive vehicle control, etc., to name a few example application scenarios.

As illustrated, a first circuit, e.g., circuit 152, couples to a first coil 160A of the transformer 156. Likewise, a second circuit, e.g., circuit 154, is coupled to a second coil 160B of the transformer 156, where the first and second coils 160A, 160B are inductively/magnetically coupled. Depending on implementation, one of the first and second coils 160A, 160B may be coupled to and/or operable at a first voltage. In similar fashion, the other one of the first and second coils 160A, 160B may be coupled to and/or operable at a second voltage that may be greater than or less than the first voltage. In operation, transformer 156 allows the first and second circuits 152, 154 to communicate with each other without a conductive connection, e.g., a wired connection, between the two circuits 152, 154 while using modulated signals across the isolation barrier. As will be set forth in detail below, a ground ring may be placed around the coil 160A and/or coil 160B, where one or more gaps or discontinuities may be provided in the ground ring in order to mitigate the risk of reduced lifetime during operation in an example application scenario, e.g., including a high voltage environment and/or an environment susceptible to high voltage transients due to discharge events.

FIG. 1B depicts a microelectronic device 100B including an isolation transformer 104 as an isolation barrier disposed between two circuits 102A, 102B according to an example. In some arrangements, the microelectronic device 100B is a variation or representative example of the microelectronic device 100A described above, where the circuits 102A and 102B are roughly analogous to the circuits 152 and 154 of FIG. 1A with additional details shown therein.

In some implementations, the microelectronic device 100B is illustrative of a semiconductor device, e.g., an integrated circuit, where circuits 102A and 102B may be provided as circuit portions operable in two voltage domains, respectively, that may require isolation therebetween. In such implementations, the isolation transformer 104 may be monolithically integrated within the integrated circuit (e.g., on a same semiconductor substrate). In some implementations, the microelectronic device 100B is illustrative of a multi-chip device, e.g., where the circuits 102A and 102B may be formed on separate substrates (e.g., chips or dies) having circuitry operating in different voltage domains. In some multi-chip implementations, the isolation transformer 104 may comprise a standalone transformer (SAX) on a separate substrate or may be integrated with one of the circuits, e.g., circuit 102A or 102B. Regardless of whether the isolation transformer 104 is integrated with either circuits 102A, 102B or provided as a standalone isolation device, the isolation transformer 104 may include a first coil 105A and a second coil 105B, either of which may be designated as a primary (or first) coil or a secondary (or second) coil depending on application. Further, analogous to the coils 160A, 160B of the transformer 156 shown in FIG. 1A, the coils 105A, 105B may be operable at different voltages. Moreover, a ground ring associated with the isolation transformer 104 may be provided with one or more gaps (also referred to as discontinuities) that may be positioned in particular locations, areas or regions relative to the layout configurations of coils 105A, 105B (or portions thereof) of the isolation transformer 104 for purposes of the present disclosure.

Without limitation, the microelectronic device 100B is illustrated as an isolator for effectuating communication between the circuits 102A and 102B disposed in a bi-directional communication system including two endpoints (not specifically shown in FIG. 1B). In one arrangement, circuit 102A may be interfaced with a first endpoint or subsystem via input/output (I/O) circuitry 106A configured to support one or more communication channels. In similar fashion, circuit 102B may be interfaced with a second endpoint or subsystem via I/O circuitry 106B configured to support a corresponding number of communication channels. Depending on the direction of communications, circuits 102A and 102B may be operable as a transmitter (Tx), a receiver (Rx), or both, e.g., on a channel-by-channel basis.

In some arrangements, communications between the circuits 102A and 102B may be effectuated using differential signaling where a communication signal on a channel is provided as a pair of differential signals across a corresponding isolation transformer 104. Differential signaling may be used in some applications for improving the performance and quality of signal transmission, e.g., with better immunity to noise. Accordingly, the microelectronic device 100B may include a plurality of isolation transformers 104 depending on the number of communication channels between the circuits 102A and 102B. With respect to each communication channel supported by the circuits 102A, 102B, a pair of ports, nodes or internal I/O terminals may therefore be provided in each circuit 102A, 102B for coupling with a respective side of a corresponding isolation transformer 104. For example, one coil of an isolation transformer 104 may be coupled between a pair of ports of one circuit with respect to a communication channel and the other coil of the isolation transformer 104 may be coupled between a corresponding pair of ports or internal I/O terminals of the other circuit. As illustrated, ports 116A-1 and 116A-2 of the circuit 102A are coupled to terminals 107A-1 and 107A-2 of the coil 105A of the isolation transformer 104. Likewise, corresponding ports 116B-1 and 116B-2 of the circuit 102B are coupled to terminals 107B-1 and 107B-2 of the coil 105B of the isolation transformer 104.

In operation, a communication signal received in one circuit, e.g., circuit 102A, on a channel for transmission to the other circuit, e.g., circuit 102B, may be coded, modulated, and conditioned as differential signals (e.g., a pair of inverted and non-inverted signals) that may be received by the other circuit across the corresponding isolation transformer 104. The other circuit 102B may include circuitry for demodulating and decoding the received signals to construct the communication signal for subsequent downstream transmission. Because the microelectronic device 100B may be configured as a bi-directional digital isolator in an example implementation, both circuits 102A, 102B may include circuitry for coding/decoding, modulation/demodulation, signal conditioning, oscillator circuitry, etc. Whereas a coding/decoding circuit 108, oscillator 110, modulation/demodulation circuit 112 and a signal conditioning circuit 114 are specifically shown as part of overall circuitry 109A of the circuit 102A, analogous circuits may also be provided as part of overall circuitry 109B of the circuit 102B in some example arrangements. Further, each circuit 102A, 102B may be provided with respective supply voltage (VDD) rails 199A, 199B and reference voltage (VSS or ground) rails 197A, 197B. Depending on application, circuits 102A and 102B may employ a variety of modulation schemes, e.g., on-off keying (OOK), phase shift keying (PSK), frequency shift keying (FSK), etc., for effectuating communications between the endpoints of the overall system.

FIG. 1C depicts a traction inverter system 100C that may include an isolation barrier block 162 comprising a transformer including a gapped ground ring according to some examples. In some arrangements, the traction inverter system 100C may be deployed in a hybrid electric vehicle (HEV) or a full electric vehicle (EV) for converting a DC supply from the vehicle's HV battery, e.g., battery 172, into AC output that powers an electric motor 168 of the vehicle. As illustrated, the traction inverter system 100C may include various blocks or modules that may be disposed or operable in respective low voltage (LV) or high voltage (HV) domains, e.g., LV domain 163A and HV domain 163B, which may be separated by the isolation barrier block 162. In some HEV/EV implementations, an LV domain may refer to voltages less than 60V-100V and an HV domain may refer to voltages over 100V. In some arrangements, the isolation barrier block 162 may include a plurality of isolation transformers (not specifically shown in FIG. 1C) depending on the type and/or number of blocks or modules requiring isolation.

In one arrangement, the traction inverter system 100C may include a power management IC (PMIC) module 166 and a microcontroller unit (MCU) 165 operable in the LV domain 163A that communicate via a controller area network (CAN) bus 167. HV domain modules may include the battery 172 (e.g., a Li-ion battery bank), a DC link capacitor 174, a plurality of sensing blocks such as temperature sensing block 171, current sensing block 173, voltage sensing block 175, and position sensing block 177, as well as various protection and monitoring blocks 176 and power transistors 180 configured to control the motor 168. In some examples, the power transistors 180 may comprise insulated-gate bipolar transistors (IGBT), SiC FETs or Group III-V devices including GaN devices. The power transistors 180 are operable to control the flow of current to the motor 168 to generate motion, and may be monitored and protected by sensing the temperature, voltage and current of the power transistors 180 during operation. Further, the power transistors 180 may be controlled by MCU 165 via gate drivers 178 that may also include suitable isolation barriers (not shown in FIG. 1C) for facilitating high side operation and low side operation of the traction inverter system 100C. Accordingly, at least a portion of the traction inverter system 100C may include a circuit arrangement similar to the arrangement shown in FIG. 1A, where a circuit or module operable in the LV domain 163A and another circuit or module operable in the HV domain 163B are isolated by and coupled via a suitable isolation transformer of the isolation barrier block 162.

During operation of the motor 168, voltage, current and position signals are sensed and fed back to MCU 165 to modify a modulation scheme (e.g., pulse-width modulation or PWM) used by the traction inverter system 100C to supply power. In some examples, feedback signals may be processed by MCU 165 for providing a field-oriented control (FOC) mechanism that utilizes mathematical transformations to generate proper control signals for driving the power transistors at suitable frequencies in order to control power output. As accurately sensed signals transmitted between LV and HV domains are important in providing efficient motor control, it is desirable that the integrity of the isolation barrier of the traction inverter system 100C is not degraded through the expected lifetime of the system. In the examples below, a ground ring arrangement will be set forth in conjunction with an isolation transformer where gaps in the ground ring may be placed at suitable locations relative to the transformer coils to improve the isolation barrier lifetime. Accordingly, the risk of the isolation barrier limiting the intended system lifetime may be reduced in the examples herein.

Additional details regarding an example implementation of the traction inverter system 100C may be found in Texas Instruments Application Note SLUA963B, “HEV/EV Traction Inverter Design Guide—Using Isolated IGBT and SiC Gate Drivers,” Revised October 2022, which is incorporated in its entirety by reference herein.

For purposes of the present disclosure, coils of an isolation transformer such as, e.g., transformers 104, 156, may be provided as planar conductive windings horizontally disposed on two different metal levels formed over a substrate, where the metal levels may be separated by one or more dielectric material layers having a suitable total thickness. In some examples where the isolation transformer is monolithically integrated in a circuit, the metal levels may be provided as part of a multilevel metal interconnect (MMI) fabricated in a back-end-of-line (BEOL) flow of the circuit. In some examples where the isolation transformer is provided as a standalone component, the metal levels may not necessarily form an MMI arrangement of an IC. Further, an isolation transformer may be provided as a center tap transformer in some arrangements where one or both coils of the transformer may be provided with a separate contact within the coil winding (e.g., at a midpoint in the winding) in addition to contacts provided at respective coil terminals, e.g., terminals 107A-1, 107A-2 of coil 105A or terminals 107B-1, 107B-2 of coil 105B shown in FIG. 1B. In additional and/or alternative arrangements, an isolation transformer may be provided as a non-center-tap transformer where there may be no contacts to the windings other than contacts at the coil terminals.

In some arrangements, a transformer coil may comprise one or more sections or portions of windings (which may also be referred to as “turns” or “loops”) separated by substantially rectilinear portions or sections (e.g., portions or sections with less curvature) that allow transitioning from one winding portion to an adjacent winding portion in a geometrical layout or configuration of the transformer. In some arrangements, a rectilinear/transitional section disposed between two winding portions of a coil may be provided with a contact operable as a center tap contact. In some arrangements, each winding portion of a transformer coil may contain a specific number of turns depending on application (e.g., tens or hundreds of turns). For example, where greater coupling between the coils is desired, more turns may be provided in corresponding winding portions of the coils. In some arrangements, the turns of a winding portion of a transformer coil may have a circular shape in a top plan view, although other shapes may be implemented in additional and/or alternative arrangements. For example, winding portions having shapes such as obround, oval, diamond, racetrack, polygonal, triangular, rectangular, square, etc., may be provided in some isolation transformers.

Further, the direction of turns in two winding portions of a transformer coil may be different in some arrangements. For example, the turns in a first winding portion of a transformer coil may have a first direction, e.g., a clockwise direction, whereas the turns in a second winding portion connected to the first winding portion via a rectilinear/transitional portion may have a second direction, e.g., a counterclockwise direction. In some arrangements, the direction of turns in the winding portions of a transformer coil may be the same, however. Regardless of the directionality of the turns in two winding portions of a transformer coil, a transitional portion connected therebetween, e.g., a rectilinear section, may be termed a crossover section or simply a “crossover” for purposes of the examples herein.

In general, the behavior of a transformer in an applied electric field is dependent on a relationship between the area of the coils and the vertical separation therebetween, which is determined by a thickness of the dielectric material(s) between the coils. FIG. 1D depicts a side elevation view of a transformer 100D including an upper coil 184A (or a winding portion thereof) overlapping a matching lower coil 184B (or a winding portion thereof). The coils 184A, 184B have an area A and are separated by a dielectric layer (not shown) having a thickness T. For purposes of the examples herein, the upper coil 184A may be referred to as a first coil and the lower coil 184B may be referred to as a second coil, and/or vice versa, depending on the context. In some arrangements, the transformer 100D is representative of transformers 156, 104 shown in FIGS. 1A and 1B, respectively. Accordingly, coils 184A, 184B of the transformer 100D may be biased appropriately during operation, e.g., the lower coil 184B may be coupled to a first voltage whereas the upper coil 184A may be coupled to a second voltage different from the first voltage.

When subjected to an electric field, the greater the distance between the coils 184A, 184B, the more the two coils 184A, 184B behave like point sources at the periphery of respective winding portions and less like conductive plates. As a result, an electric field 183 may be concentrated at the periphery of the winding portions of the coils 184A, 184B, e.g., shown as local field concentrations 182 in FIG. 1D. Further, the electric field 183 may have a gradient such that the electric field 183 may be stronger at the edge of the outer turns of the winding portions and weaker at locations spaced apart from the edge. Moreover, coil winding portions having turns that include high curvature features (e.g., sharp turns) at the periphery may increase localized electric field concentrations that may limit the lifetime of the dielectric material.

Because the gaps in a ground ring may present anomalies that may further increase the localized electric field, examples of the present disclosure may be configured to provide a gapped ground ring around a coil, e.g., coil 184B, where gaps in the ground ring may be positioned in locations distal with respect to winding portion features having a propensity to cause or increase localized electric field concentrations. As will be set forth below, crossover sections disposed between winding portions of coils may have less propensity for causing or increasing electric filed concentrations in some example transformer configurations. Further, crossover sections may demarcate a region between the winding portions into areas that may have localized weaker electric fields. Accordingly, ground ring gaps may be advantageously placed at such locations or areas in a transformer configuration according to the teachings herein, where noise immunity as well as dielectric lifetime may be simultaneously improved.

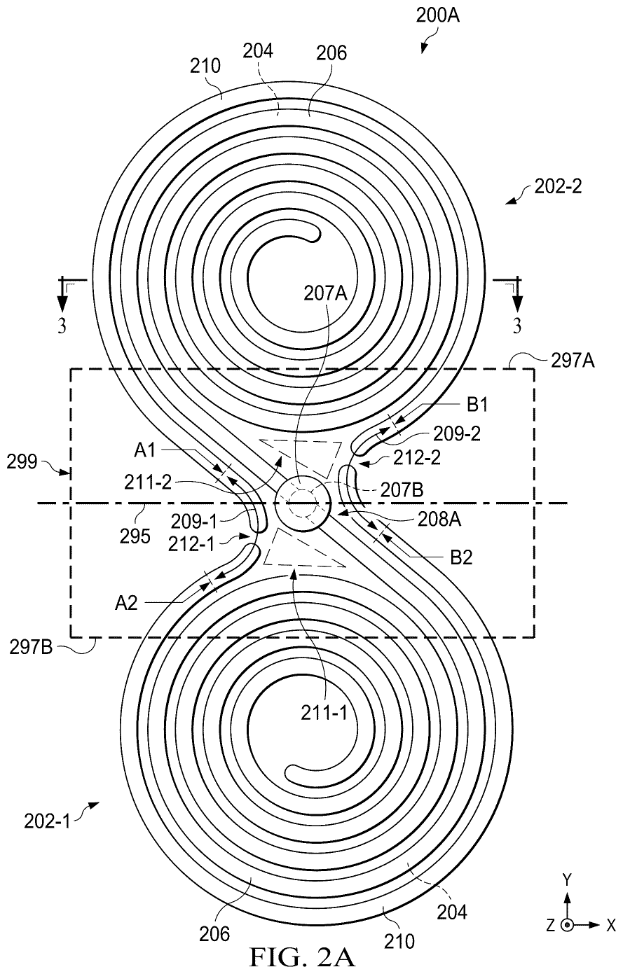

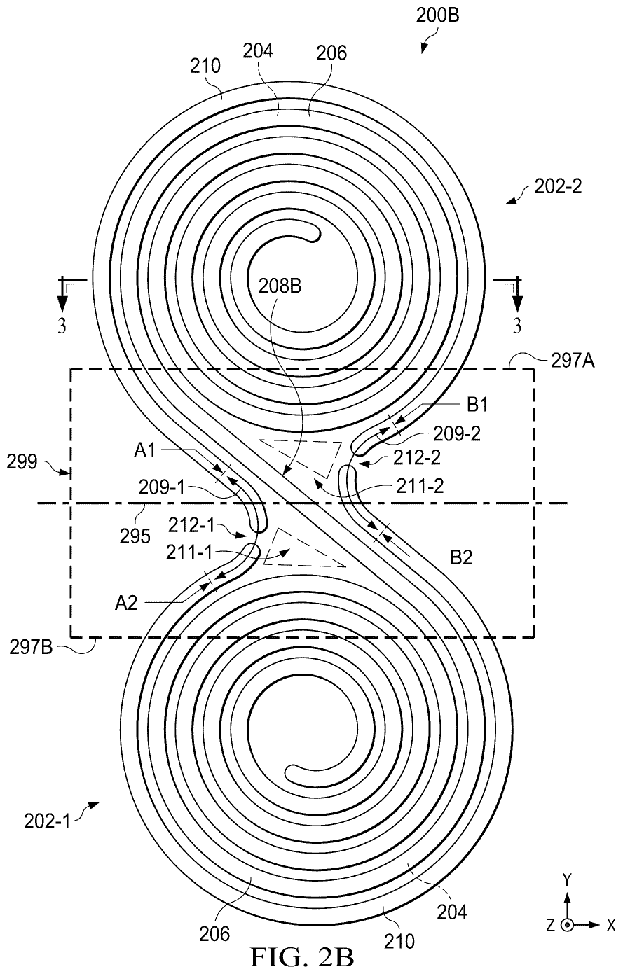

FIGS. 2A and 2B illustrate top plan views of two isolation transformer configurations, respectively, which include a ground ring having discontinuities according to some examples. In the example of FIG. 2A, isolation transformer 200A is representative of a center tap (CT) transformer including two winding portions 202-1 and 202-2 for each of matching coils 204, 206, where coil 206 is an upper coil that overlies or overlaps coil 204 disposed over a substrate (not shown). Isolation transformer 200B depicted in FIG. 2B is representative of a non-center-tap (nCT) transformer including the matching coils 204, 206, where each coil includes two adjacent winding portions 202-1 and 202-2 identical to the arrangement of transformer 200A of FIG. 2A. Transformers 200A, 200B include a respective crossover section 208A, 208B disposed between the winding portions 202-1 and 202-2. Whereas contacts 207A and 207B (also referred to as center tap contacts or CT contacts) are provided with respect to the upper and lower coils 206, 204, respectively, in the crossover section 208A of the transformer 200A in order to facilitate the center tap configuration, such contacts are absent in the crossover section 208B of the transformer 200B. In addition to the contacts 207A, 207B of the crossover section 208A, respective end terminals of the upper and lower coils 206, 204 of the transformers 200A, 200B may also be provided with contacts (also referred to as terminal contacts; not specifically shown in the views of FIGS. 2A and 2B).

As illustrated in FIGS. 2A and 2B, coil winding configurations of the transformers 200A and 200B are essentially identical apart from center tap contacts 207A, 207B provided in the crossover section 208A of the transformer 200A. Accordingly, set forth below is a description of the transformer 200A that is equally applicable to the transformer 200B for purposes of some examples herein unless otherwise noted.

In one arrangement, winding portions 202-1 and 202-2 of the upper and lower coils 206, 204 of the transformer 200A may each contain a same number of turns although it is not a requirement. Whereas the winding portions 202-1 and 202-2 are illustrated as containing turns having a circular shape, the turns may have different shapes in additional and/or alternative arrangements as previously noted. Further, the winding portions 202-1 and 202-2 are arranged in a “FIG. 8” configuration resulting in a crossover, e.g., a generally rectilinear crossover section 208A (FIG. 2A) or 208B (FIG. 2B), in a region 299 between the two winding portions 202-1 and 202-2. Whereas a FIG. 8 configuration may be provided in some examples to maximize the number of turns in the coils as well as reduce noise, different winding topologies or layout configurations may be implemented to obtain similar benefits in additional and/or alternative examples. Accordingly, other layout configurations of the winding portions 202-1 and 202-2 are within the scope of the present disclosure.

In some arrangements, a ground ring 210 surrounding outermost turns of the lower coil 204 may be provided, where the ground ring 210 may extend on each side of the crossover section 208A of the transformer 200A, or similarly on each side of the crossover section 208B of the transformer 200B. One segment of the ground ring 210 may follow the path of the outermost turn of the winding portion 202-1 with about a constant spacing from the winding portion 202-1. This segment generally has a curvature defined as “concave-in” or as “negative radius of curvature”, where “in” refers to the direction toward the lower coil 204. Similarly, another segment of the ground ring 210 may follow the path of the outermost turn of the winding portion 202-2 with about a constant spacing from the winding portion 202-2, and is also concave-in, having a negative radius of curvature. Segments of the ground ring 210 that extend parallel to the crossover section 208A (or 208B) may also be rectilinear. Thus, one rectilinear segment of the ground ring 210 extends between the concave-in portion of the ground ring 210 around the winding portion 202-1 and the winding portion 202-2. Another rectilinear segment of the ground ring 210 extends between the concave-in portion of the ground ring 210 around the winding portion 202-2 and the winding portion 202-1. Unless otherwise needed for clarity of the description, the rectilinear portions of the ground ring 210 are considered a part of the concave-in segment from which they directly extend.

The concave-in segments are joined by at least one “concave-out”, or “positive radius of curvature” segment 209-1, 209-2, where “out” refers to the direction away from the lower coil 204. Thus in one arrangement a concave-out segment 209-1 joins the rectilinear segment of the ground ring 210 around the winding portion 202-2 to the ground ring segment around the winding portion 202-1. As illustrated, the concave-out segment 209-1 is a portion of the ground ring 210 between points A1 and A2. In similar fashion, another concave-out segment 209-2 joins the rectilinear segment of the ground ring 210 around the winding portion 202-1 to the ground ring segment around the winding portion 202-2, where the concave-out segment 209-2 is a portion of the ground ring 210 between points B1 and B2. As described more fully below, the concave-out segments 209-1 and 209-2 need not be continuous.

For purposes of the present disclosure, region 299 between the winding portions 202-1 and 202-2 may be defined based on the topological/geometric configuration of the winding portions 202-1 and 202-2. In some arrangements, region 299 may be defined as a region including or surrounding the crossover section 208A between the winding portions 202-1 and 202-2. Depending on implementation, region 299 may take on any suitable shape based on electric field gradients that may be expected near the crossover section 208A in an application environment. In some implementations, region 299 may include a top long side 297A and a bottom long side 297B that are roughly parallel to a horizontal axis, e.g., the X-axis, of the transformer 200A. In some implementations, the top and bottom long sides 297A, 297B may be closer to a centerline 295 that traverses the crossover section 208A, e.g., bisecting the crossover section 208A. In some implementations, the top and bottom long sides 297A, 297B may be spaced farther from the centerline by a distance. For example, the top long side 297A may be along a first X-Z plane that bisects the winding portion 202-2. Likewise, the bottom long side 297B may be along a second X-Z plane parallel to the first X-Z plane and bisects the winding portion 202-1.

In some examples, the crossover sections 208A, 208B may be configured to create partially enclosed areas 211-1, 211-2 in the region 299 near the outermost turns of the winding portions 202-1 and 202-2, respectively. In the illustrated arrangement the area 211-1 is bounded by the crossover section 208A, the winding portion 202-1 and the concave-out segment 209-1. Likewise, the area 211-2 is bounded by the crossover section 208A, the winding portion 202-2 and the concave-out segment 209-2. In some arrangements where the crossover sections 208A/208B extend across the region 299 at an angle, the partially enclosed areas 211-1, 211-2 may have a substantially triangular or wedge-shaped area that tapers to form a respective vertex near the outermost turns of the winding portions 202-1, 202-2 as shown in FIGS. 2A and 2B.

According to the examples herein, partially enclosed areas 211-1 and 211-2 located in the region 299 between two adjacent winding portions, e.g., winding portions 202-1 and 202-2, may be configured to have lower electric fields than other peripheral locations of the coils 204, 206 during operation of the transformer, e.g. by spacing from proximate grounded metal features (not shown). Accordingly, in some example arrangements, gaps, breaks, slits, or discontinuities, etc. (collectively referred to as “gaps”) having appropriate sizes may be provided in the ground ring 210 such that the gaps are positioned in or adjacent the areas 211-1, 211-2 between the winding portions 202-2 in order to minimize the localized increase in electric field while benefiting from noise immunity provided by the gaps in the ground ring 210.

By way of illustration, gaps 212-1, 212-2 are provided in the ground ring 210 surrounding the lower coil 204 of the transformer 200A. In the illustrated examples of FIGS. 2A and 2B the gap 212-1 is located within the concave-out segment 209-1, and the gap 212-2 is located within the concave-out segment 209-2. In some examples, each gap 212-1, 212-2 may be positioned on a respective side of the centerline 295 that traverses the region 299, e.g., bisecting the crossover section 208A therein as noted above. In some examples, a first gap, e.g., gap 212-1, may be positioned adjacent the partially enclosed area 211-1 in a lower half of the region 299 proximate to the winding portion 202-1. Likewise, a second gap, e.g., gap 212-2, may be positioned adjacent the partially enclosed area 211-2 in an upper half of the region 299 proximate to the winding portion 202-2.

In some arrangements, the gaps 212-1, 212-2 may be symmetrically positioned on each side of the crossover section 208A in respective partially enclosed areas 211-1, 211-2 as shown in FIG. 2A. In some examples, more than one gap may be provided on each side of a crossover section, e.g., crossover section 208A. In some examples, more than one ground ring surrounding the lower coil 204 may be provided, where each ground ring may have respective gaps positioned on either side of the crossover section 208A. However, such arrangements including multiple ground rings may increase the size of the die or circuit containing the transformer 200A. In similar manner, variations of gaps 212-1 and 212-2 in the ground ring 210 may also be provided with respect to the transformer 200B shown in the example of FIG. 2B.

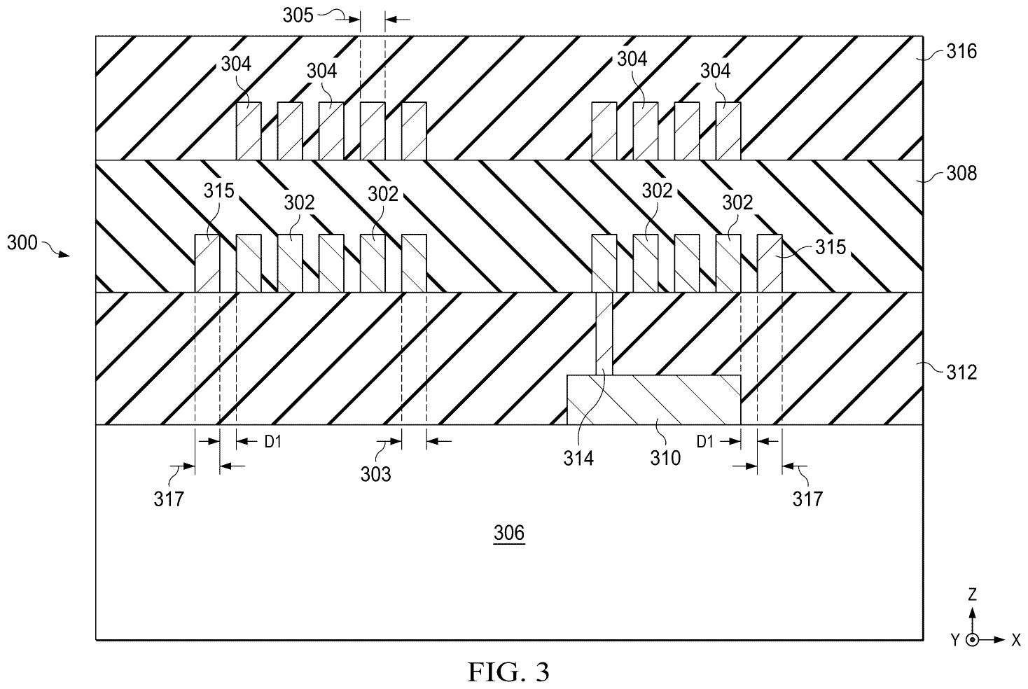

FIG. 3 depicts a cross-sectional view of an isolation transformer 300 including a ground ring according to some examples. In one example, the isolation transformer 300 is illustrative of cross-sectional views of the transformers 200A, 200B along a vertical plane, e.g., X-Z plane orthogonal to a horizontal plane defined by X- and Y-axes, as shown in FIGS. 2A and 2B. In FIG. 3, coil 302 is an example of the lower coil 204 and coil 304 is an example of the upper coil 206. A first level metal layer (e.g., MET1 or M1 level) 310 is formed and disposed over a substrate 306. In some examples, the substrate 306 may include a top insulating layer, such as an oxide layer, on a suitable semiconductor substrate so that first level metal layer 310 is on and in contact with the insulating layer (not shown in FIG. 3).

Depending on implementation, the insulated substrate 306 may include a semiconductor substrate that may predominantly comprise suitably doped silicon in some examples. In additional and/or alternative arrangements, the semiconductor substrate may comprise other semiconductor materials such as Ge, SiGe, GaAs, SiC, GaN, other Group III-V materials, etc., where one or more epitaxial layers or single-crystal layers may be formed or provided in certain areas of the semiconductor substrate 306.

In one example, first level metal layer 310 may comprise an aluminum (Al) layer with a titanium (Ti) adhesion layer on a first surface that contacts the substrate 306, a bottom titanium nitride (TiN) barrier layer on the titanium layer to mitigate electromigration of the overlying Al layer, and a top TiN layer on a second, opposite surface of first level metal layer 310 to provide both electromigration mitigation and an antireflective coating for improved photolithographic patterning. In other examples, first level metal layer 310 may comprise a material such as copper (Cu), gold (Au) or another conductor. Suitable photolithography process may be performed to pattern the first level metal layer 310. A first interlevel dielectric (ILD) layer 312 including a combination of high-density plasma (HDP) chemical vapor deposition (CVD) and plasma-enhanced chemical vapor deposited (PECVD) oxide layer may be formed over first level metal layer 310 and substrate 306. A subsequent photolithography process may be performed to form an opening in ILD layer 312. A conductive material such as Ti, TiN, tungsten (W) and/or alloys thereof may be deposited to fill the opening to form a via 314.

A second level metal layer (e.g., MET2 or M2) deposited on ILD layer 312 may be patterned to form a first coil 302 comprising a plurality of windings or turns, which is illustrative of the lower coil 204 as noted above. In some examples, a MET2 conductive member forming the windings of coil 302 may have a thickness or width 303 (e.g., along the X-axis) ranging from about 5 μm to about 10 μm. Via 314 contacts one end or terminus of first coil 302 and the first level metal layer 310, thus providing a conductive connection between a bond pad (not shown in FIG. 3) and the first coil 302. Another portion of first level metal layer 310 and another via (not shown in FIG. 3) provides contact to the other end or terminus of first coil 302. In some examples, the first coil 302 may comprise metallic layers/compositions similar to the metallic layers/compositions of the first metal layer 310 set forth above. In one arrangement, the first coil 302 may comprise an Al layer with a Ti adhesion layer on the surface where first coil 302 contacts first ILD layer 312, a bottom TiN layer between the Ti adhesion layer and the Al layer to improve electromigration, and a top TiN layer on the opposing surface of first coil 302 for electromigration enhancement and as an antireflective coating for improved photolithographic patterning.

In some examples, a ground ring 315 may be formed as a MET2 feature surrounding the outermost turn of the first coil 302. Depending on implementation, the ground ring 315 may have a thickness or width 317 (e.g., along the X-axis) that may be same as or different than the thickness or width of an individual turn of the first coil 302. In some examples, the ground ring 315 may have a width 317 ranging from about 10 μm to about 20 μm. In some examples, the ground ring 315 may comprise aluminum and may have adhesion layers on top and bottom surfaces. Further, the ground ring 315 may be laterally spaced apart from the outermost turn of the first coil 302 by a distance D1, which may range from about 5 μm to about 15 μm. As previously noted, the ground ring 315 may include one or more gaps in a location adjacent to a crossover section that extends from the outermost turn of one winding portion to the outermost turn of another winding portion of the first coil 302 in some example arrangements.

A second ILD layer 308 comprising a combination of HDP oxide, nitride, oxynitride and/or PECVD tetraethyl orthosilicate (TEOS) may be formed over the first coil 302, first ILD layer 312 and the ground ring 315. In some arrangements, the second ILD layer may have a thickness of about 15 μm to 25 μm. A third level metal layer (e.g., MET3 or M3) may be patterned using photolithography for forming a second coil 304 on the second ILD layer 308. Accordingly, at least a portion of the second ILD layer 308 may be operable as a dielectric layer between the coils 302 and 304. In an example arrangement, the second coil 304 is illustrative of the upper coil 206 shown in FIGS. 2A and 2B. In some arrangements, the second coil 304 may comprise a same number of turns as the first coil 302. In some arrangements, a MET3 conductive member forming the windings of coil 304 may have a same thickness or width 305 (e.g., along the X-axis) as the windings of coil 302, e.g., ranging from about 5 μm to about 10 μm. The third level metal layer may include bond pads (not shown in FIG. 3) that provide connection to respective ends/termini of the second coil 304. In one example, the second coil 304 may comprise metallic layers/compositions similar to the metallic layers/compositions of the first coil 302 as set forth above. A protective overcoat (PO) layer 316 of suitable thickness may be provided for covering the second coil 304 of the transformer 300. In some examples, PO layer 316 may comprise multiple layers/sublayers of different materials such as HDP oxide, TEOS oxide, PECVD SiON, and the like, and may have a thickness ranging from about 0.5 μm to about 10 μm, depending on implementation.

A varying signal from a circuit such as the first circuit 152 (shown in FIG. 1A) on, for example, the second coil 304 induces an induced signal on the first coil 302. The induced signal may be decoded by a circuit such as the second circuit 154 (shown in FIG. 1A) that may be connected to the first coil 302.

Although the first and second coils 302, 304, and the ground ring 315 may be formed using subtractive etching processes as set forth above, the first and second coils 302, 304, and the ground ring 315 may also be formed using a suitable damascene process including copper in additional and/or alternative arrangements.

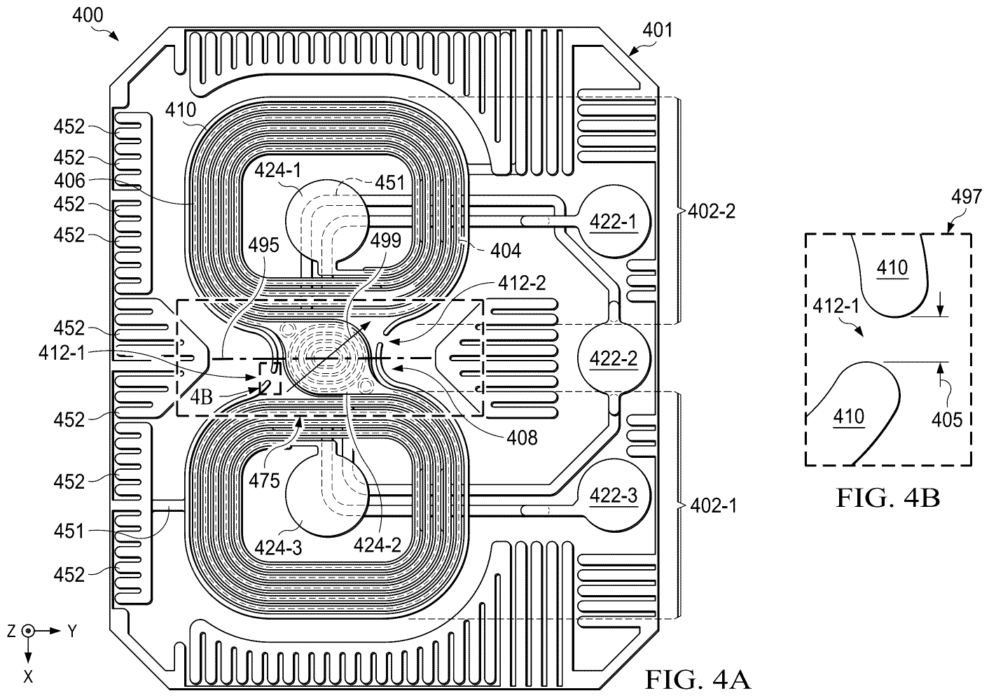

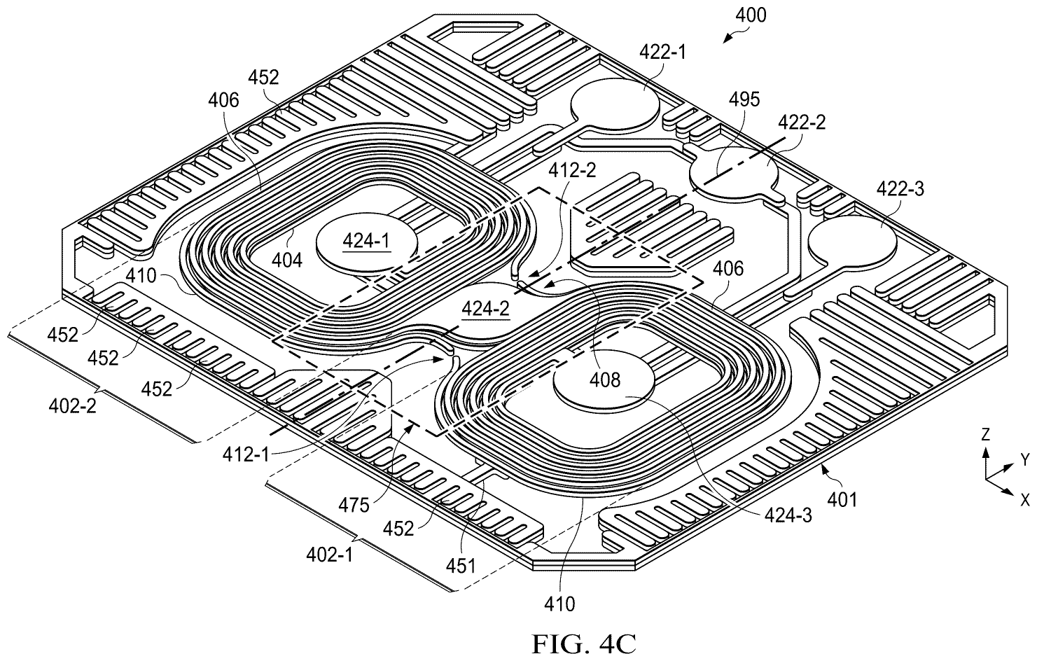

FIGS. 4A and 4C illustrate two views of an isolation transformer 400 including a ground ring according to some examples. In particular, FIG. 4A depicts a top plan view of the isolation transformer 400 and FIG. 4C depicts a perspective view of the isolation transformer 400, where FIG. 4B depicts a magnified thumbnail view pertaining to a ground ring gap of the isolation transformer 400. In the example of transformer 400, substrate 401 may be provided as a separate substrate from the substrates of the circuits, e.g., circuits 152, 154 of FIG. 1A or circuits 102A, 102B of FIG. 1B, that may be coupled to the transformer 400. In some arrangements, the transformer 400 may be packaged in a hybrid package with various devices or components coupled to it (e.g., as a multichip module). For example, with respect to the microelectronic device 100A, the transformer 400 is an example of transformer 156 (FIG. 1A) that may be packaged in a hybrid package with the first circuit 152 and the second circuit 154. In other examples, the transformer 400 may be formed on the same substrate as either the first circuit 152 or the second circuit 154, as previously noted. In another example, the transformer 400, first circuit 152 and second circuit 154 may be formed in the same substrate. Where high voltage deployment scenarios are contemplated, a hybrid package with separate substrates for the isolation transformer 400 and corresponding circuits such as circuits 152 and 154 may provide additional isolation between components and thus more robustness.

In some arrangements, the isolation transformer 400 is illustrative of the transformer 200A having a CT configuration. Similar to the transformer 200A, isolation transformer 400 includes a lower coil 404 (e.g., a first coil) and an upper coil 406 (e.g., a second coil) configured as two winding portions 402-1 and 402-2 with a crossover section 408 disposed therebetween in a FIG. 8 arrangement. Further, a region 475 may be defined between the winding portions 402-1 and 402-2 similar to the region 299 shown in FIGS. 2A and 2B. In similar fashion, a centerline 495 traversing the crossover section 408 (e.g., bisecting the crossover section 408) may be defined. As illustrated, bond pads 422-1 to 422-3 are coupled to the respective termini of the lower coil 404 and at a center tap provided in the crossover section 408 thereof. Likewise, bond pads 424-1 to 424-3 are coupled to the respective termini of the upper coil 406 and at a center tap provided in the crossover section 408 thereof.

The isolation transformer 400 includes a ground ring 410 surrounding the outermost turn of the lower coil 404, where the ground ring 410 may have a connection 451 to one or more shielding members or fingers 452 provided along a periphery of the substrate 401. In this example, the ground ring 410 includes two gaps 412-1, 412-2, with the gaps may be positioned on respective sides of the crossover section 408 of the transformer 400. Further, gaps 412-1, 412-2 may be positioned in respective sides of the centerline 495. As shown, gap 412-1 is disposed on one side of the centerline 495, rendering the gap 412-1 positioned closer to the winding portion 402-1. In similar manner, gap 412-2 is disposed on a second, opposite side of the centerline 495, rendering the gap 412-2 positioned closer to the winding portion 402-2.

In some arrangements, the gaps 412-1, 412-2 may be located diagonally with respect to each other across the crossover section 408. For example, a gap axis 499 passing through the crossover section 408 at an angle relative to the centerline 495 may be defined for an isolation transformer application for facilitating symmetrical placement of the gaps 412-1, 412-2. In one example implementation, the gap axis 499 may be oriented at an angle, e.g., varying from 30° to 80°, with respect to the centerline 495 that is parallel to a horizontal axis, e.g., the Y-axis in this example. Based on the orientation of the gap axis 499, the gaps 412-1 and 412-2 may be placed along or aligned with the gap axis 499 in partially closed areas (e.g., symmetrical with respect to the gap axis 499) that are proximate to the crossover section 408. Depending on implementation, the gaps 412-1, 412-2 may have a width 405 ranging from about 5 μm to about 15 μm, as shown in a detail 497 of the gap 412-1 in FIG. 4B. In some arrangements, gaps that are too close or narrow, e.g., less than 3 μm, may degrade the signal-to-noise (S/N) ratio of the communication channel, whereas gaps wider than 15 μm may lead to higher/increased localized electric fields that could limit the dielectric lifetime.

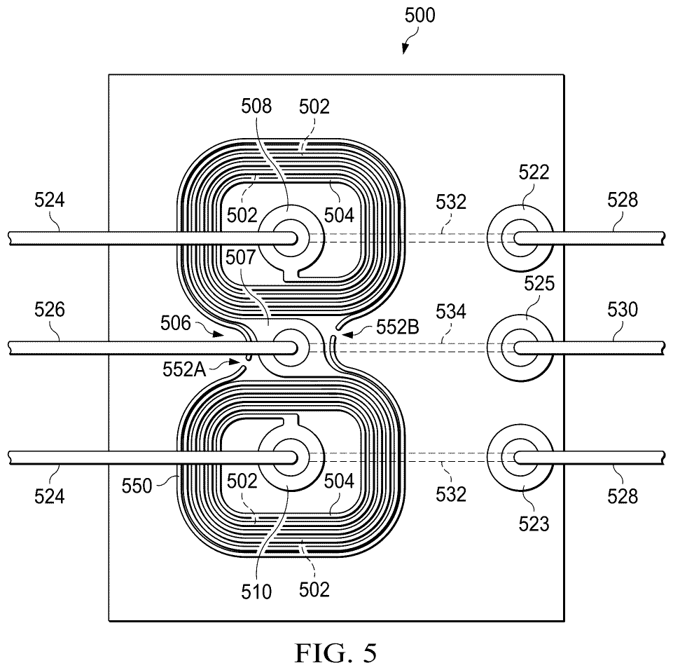

FIG. 5 illustrates a center tap isolation transformer 500 including a ground ring 550 according to an example where crossover 506 is a representative arrangement of the crossover section 408 shown in FIGS. 4A/4C. In this example, bond wires and pads associated with first and second coils 502, 504 of the transformer 500 are depicted to illustrate center tap connectivity of the respective coils 502, 504 having a FIG. 8 configuration. As illustrated, the first and second coils 502 and 504 are examples of lower and upper coils 404 and 406, respectively of the transformer 400 of FIGS. 4A/4C.

Bond wires 524 are configured to couple to a first bond pad 508 and a second bond pad 510 associated with two termini of the upper coil 504. Another bond wire 526 is configured to couple to a center tap bond pad 507. In this example, bond pads 508 and 510 are examples of bond pads 424-1 and 424-3, respectively, and bond pad 507 is an example of bond pad 424-2 shown in FIGS. 4A/4C.

In similar fashion, three bond pads may be provided with respect to the lower coil 502, where respective conductive leads are provided for facilitating connectivity between bond pads and termini and center tap contact of the lower coil 502. As illustrated, leads 532 may be configured to couple respective termini of the lower coil 502 to corresponding bond pads 522 and 523. Further, lead 534 may be configured to couple a center tap contact (not shown in FIG. 5) of the lower coil 502 to a corresponding bond pad 525. In this example, bond pads 522 and 523 are examples of bond pads 422-1 and 422-3, respectively, and bond pad 525 is an example of bond pad 422-2 shown in FIGS. 4A/4C. Analogous to bond wires 524, 526 provided with respect to the upper coil 504, bond wires 528 may be coupled to bond pads 522, 523 and bond wire 530 may be coupled to bond pad 525 with respect to the lower coil 502.

As previously noted, the lower and upper coils 502, 504 may be separated by a dielectric layer of suitable thickness (not shown in FIG. 5). Depending on implementation and biasing of the lower and upper coils 502, 504, ground ring 550 may surround either coil in an example arrangement. Further, the ground ring 550 may include gaps 552A and 552B that may be placed on respective sides of the crossover 506 proximate to the center tap contact of respective coils. Accordingly, the gaps 552A, 552B may be positioned at locations spaced apart from high curvature portions of the peripheral turns of the upper coil 504 and/or lower coil 502. In an example arrangement, bond wires 524, 526 and bond wires 528, 530 may be configured to provide connectivity with external circuitry, e.g., circuits 152 and 154, respectively, of FIG. 1A, circuits 102A and 102B, respectively, of FIG. 1B, or MCU 165 and sensing modules 171-177 of FIG. 1C, where improved dielectric performance, e.g., extending dielectric lifetime, while maintaining noise immunity is desired in the system.

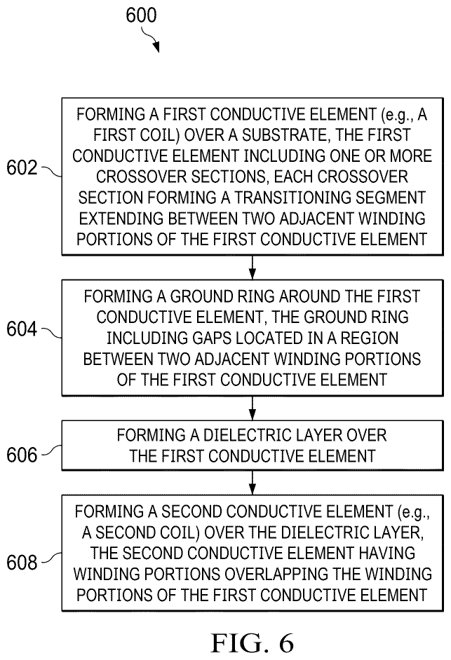

FIG. 6 is a flowchart of a method 600 according to an example of the present disclosure. At block 602, a first conductive element (e.g., a first coil) including two or more winding portions may be formed over a substrate, where the first conductive element may include one or more crossover sections. In some examples, each crossover section may form a transitioning segment (e.g., a rectilinear segment having less curvature) extending between two adjacent winding portions of the first conductive element. At block 604, a ground ring may be formed around the first conductive element, where the ground ring includes gaps located in a region between two adjacent winding portions of the conductive element that experience lower electric field concentrations. In some examples, a crossover section of the first conductive element may form partially enclosed areas in the region between the adjacent winding portions that may be configured to have lower electric field concentrations. At block 606, a dielectric layer may be formed over the first conductive element. Depending on application, the dielectric layer may have a suitable thickness as previously noted (e.g., a thicker dielectric layer for applications required to withstand several hundreds or thousands of volts). In some examples, the dielectric layer may have a thickness ranging from about 15 μm to about 30 μm. At block 608, a second conductive element (e.g., a second coil) may be formed over the dielectric layer, where the second conductive element may have winding portions overlapping the winding portions of the first conductive element.

In one variation where there may be no crossover sections in the coil windings of a transformer, some examples of the present disclosure may include providing one or more gaps in a ground ring at locations proximate to peripheral sections of the windings that are more rectilinear than curvilinear. As previously noted, coil windings having sharp corners or curves may have or generate more concentrated electric fields, rendering ground ring gaps at such locations more susceptible to reduced dielectric lifetime. Accordingly, some examples of the present disclosure may be configured so as to place ground ring gaps spatially apart from such locations.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise. With respect to terms indicating a relative degree of variation in a value of a parameter or variable, such as, “around”, “about”, “approximately”, etc., such terms may indicate a percentage or fraction of variation in the value of the parameter or variable, e.g., ±5%, ±10%, etc., depending on the context unless otherwise specified.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. An isolation transformer, comprising:
a first coil;
a second coil;
a dielectric layer between the first coil and the second coil; and
a ground ring around the first coil, the ground ring including at least one gap in a region between a first winding portion of the first coil and a second winding portion of the first coil.

2. The isolation transformer of claim 1, wherein the region between the first and second winding portions of the first coil includes a crossover section of the first coil, the crossover section extending between the first and second winding portions of the first coil and forming a partially enclosed area near the first winding portion in the region, and wherein the at least one gap is positioned in the partially enclosed area.

3. The isolation transformer of claim 1, wherein the region between the first and second winding portions of the first coil includes a crossover section of the first coil, the crossover section extending between the first and second winding portions of the first coil and forming a first partially enclosed area near the first winding portion in the region and a second partially enclosed area near the second winding portion, and wherein the ground ring includes two gaps positioned in respective partially enclosed areas.

4. The isolation transformer of claim 1, wherein the at least one gap is in a concave-out segment of the ground ring located in the region.

5. The isolation transformer of claim 1, wherein the at least one gap is about 5 μm to 15 μm wide.

6. The isolation transformer of claim 1, wherein the first coil and the second coil are each configured as a center tap coil.

7. The isolation transformer of claim 1, wherein the first coil and the second coil are each configured as a non-center tap coil.

8. A semiconductor device, comprising:
a first circuit;
a second circuit; and
an isolation transformer between the first and second circuits, the isolation transformer including:
a first conductive element over a substrate, the first conductive element including a first winding portion, a second winding portion and a crossover section extended between the first and second winding portions;
a ground ring around the first conductive element, the ground ring including a discontinuity positioned in an area between the first winding portion of the first conductive element and a centerline bisecting the crossover section;
a dielectric layer over the first conductive element and the ground ring; and
a second conductive element over the dielectric layer, the second conductive element including a first winding portion, a second winding portion and a crossover section extended between the first and second winding portions, the first and second winding portions and the crossover section of the second conductive element respectively overlapping the first and second winding portions and the crossover section of the first conductive element.

9. The semiconductor device of claim 8, wherein the isolation transformer is a center tap standalone transformer.

10. The semiconductor device of claim 8, wherein the isolation transformer is a non-center tap standalone transformer.

11. The semiconductor device of claim 8, wherein the discontinuity is a first discontinuity and the ground ring includes a pair of discontinuities including the first discontinuity and a second discontinuity, and wherein the second discontinuity is positioned in an area between the centerline bisecting the crossover section and the second winding portion of the first conductive element.

12. The semiconductor device of claim 11, wherein the first discontinuity is positioned on one side of the crossover section and the second discontinuity is positioned on another, opposite side of the crossover section.

13. The semiconductor device of claim 8, wherein the discontinuity is a gap of about 5 μm to 15 μm wide.

14. The semiconductor device of claim 8, wherein the ground ring is laterally spaced apart from an outermost turn of the first conductive element by a uniform distance.

15. A method, comprising:
forming a first coil over a substrate, the first coil including a crossover section extended between two adjacent winding portions of the first coil;
forming a ground ring around the first coil, the ground ring including a gap in a region between the two adjacent winding portions;
forming a dielectric layer over the first coil; and
forming a second coil over the dielectric layer, the second coil overlapping the first coil and including a crossover section extended between two adjacent winding portions of the second coil.

16. The method of claim 15, wherein the gap is a first gap and the ground ring is formed to include a pair of gaps including the first gap and a second gap, and wherein the first gap is positioned in a first area of the region, the first area disposed between a centerline bisecting the crossover section and a first winding portion of the first coil and the second gap is positioned in a second area of the region, the second area disposed between the centerline and a second winding portion of the first coil, the first and second winding portions forming the two adjacent winding portions of the first coil.

17. The method of claim 16, wherein the first gap is located on a first side of the crossover section and the second gap is located on a second, opposite side of the crossover section.

18. The method of claim 16, wherein the first gap is located adjacent to the first winding portion of the first coil and the second gap is located adjacent to the second winding portion of the first coil.

19. The method of claim 15, wherein the gap is about 5 μm to 15 μm wide.

20. The method of claim 15, wherein the dielectric layer is about 15 μm to 30 μm thick.
